(19) United States
(12) Patent Application Publication
(10) Pub. No.: US 2009/0251040 A1
(43) Pub. Date: Oct. 8, 2009

(54) TRANSPARENT ELECTRIC SIGN AND CHIP LED APPLIED THERETO

(76) Inventor: Sung Kyu Kim, Paju-si (KR)

Correspondence Address: PARK LAW FIRM, 3255 WILSHIRE BLVD, SUITE 1110, LOS ANGELES, CA, 90010, US

(21) Appl. No.: 12/095,954

(22) PCT Filed: Aug. 1, 2006
(86) PCT No.: PCT/KR06/03023

§ 371 Date: Jul. 14, 2008

(30) Foreign Application Priority Data
Dec. 13, 2005 (KR) 10-2005-0122471

(51) Int. Cl. H01J 1/00; H01L 33/00

(52) U.S. Cl. 313/307; 257/99; 257/E33.066

(57) ABSTRACT

A transparent electric sign with chip LEDs is disclosed. The transparent electric sign comprising a first transparent board; a second transparent board being spaced apart from the first transparent board at a predetermined distance and facing the first transparent board; a transparent electrode for forming a plurality of first electrode regions and a plurality of second electrode regions which are arrayed in a matrix form, respectively, wherein at least one of the plurality of first electrode regions is adjacent to four second electrode regions; a plurality of chip LEDs adhered to the transparent electrode, wherein the chip LED has a pair of anode electrodes connected to the pair of first electrode regions being adjacent to each other and a pair of cathode electrodes connected to the pair of second electrode regions being adjacent to the pair of first electrode regions to which the anode electrode regions are connected, respectively such that the plurality of first electrode regions form a plurality of first signal lines formed in a first direction and the plurality of second electrode regions form a plurality of second signal lines formed in a second direction crossing the first direction; and a controller selectively supplying control signals to the plurality of first signal lines and the plurality of second signal lines to selectively turn on/off the plurality of chip LEDs. Therefore, the transparent electric sign is operable under low power consumption and has a long life span. The transparent electric sign can be manufactured to be transparent and thin.

### TECHNICAL FIELD

The present invention relates to a transparent electric sign, and more particularly to a transparent electric sign that can display moving images, and to a chip LED applied thereto.

### BACKGROUND ART

Electrically-illuminated signs which are installed to the outside of a house generally use light emitting diodes (LEDs) as their light sources. Since the LEDs are operated under relatively low power consumption and have a relatively long life span, they are applied to various electric signs, such as to large-sized electrically-illuminated signs installed to the exterior of a house, and to small-sized electrically-illuminated signs which are installed to the interior of a house.

However, the conventional electrically-illuminated sign is disadvantageous because it is relatively thick. These signs must be thick to accommodate electric wiring and other elements required for implementing moving images. Specifically, since circuit boards for driving the LEDs are configured in multi-layers, conventional electrically-illuminated signs are thick.

Also, since the back of conventional electrically-illuminated signs are generally covered to shield electric wires, the framework for the cover makes these signs thick, and furthermore causes them to be unattractive.

### DISCLOSURE OF INVENTION

### Technical Problem

Therefore, the present invention has been made in view of the above problems, and it is an object of the present invention to provide a thin transparent electric sign which is made of transparent material, for displaying moving images using LEDs that is operable under low power consumption and has a long life span, wherein the transparent electric sign utilizes a chip LED.

### Technical Solution

In accordance with an aspect of the present invention, the above and other objects can be accomplished by the provision of a transparent electric sign comprising: a first transparent board; a second transparent board being spaced apart from the first transparent board at a predetermined distance and facing the first transparent board; a transparent electrode for forming a plurality of first electrode regions and a plurality of second electrode regions which are arrayed in a matrix form, respectively, wherein at least one of the plurality of first electrode regions is adjacent to four second electrode regions; a plurality of chip LEDs adhered to the transparent electrode, wherein the chip LED has a pair of anode electrodes connected to the pair of first electrode regions being adjacent to each other and a pair of cathode electrodes connected to the pair of second electrode regions being adjacent to the pair of first electrode regions to which the anode electrode regions are connected, respectively such that the plurality of first electrode regions form a plurality of first signal lines formed in a first direction and the plurality of second electrode regions form a plurality of second signal lines formed in a second direction crossing the first direction; and a controller selectively supplying control signals to the plurality of first signal lines and the plurality of second signal lines to selectively turn on/off the plurality of chip LEDs.

In accordance with another aspect of the present invention, there is provided a transparent electric sign comprising: a first transparent board; a second transparent board being spaced apart from the first transparent board at a predetermined distance and facing the first transparent board; a transparent electrode forming a plurality of first electrode regions and a plurality of second electrode regions which are arrayed in a matrix form, respectively, wherein at least one of the plurality of first electrode regions is adjacent to four second electrode regions; a plurality of line forming chips adhered to the transparent electrode, wherein the line forming chip has a pair of first electrodes connected to a pair of first electrode regions being adjacent to each other, respectively, and electrically connected to each other, and a pair of second electrodes connected to the pair of second electrode regions, respectively, which are adjacent to the pair of the first electrode regions to which the first electrode is connected, and which are connected to each other, such that the plurality of first electrode regions form a plurality of first signal lines formed in a first direction, and the plurality of second electrode regions form a plurality of second signal lines formed in a second direction crossing the first direction; a plurality of chip LEDs having an anode electrode connected to one of the first electrode regions to be connected to the first signal line, and a cathode electrode connected to one of the second electrode regions to be connected to the second signal line; and a controller selectively supplying control signals to the plurality of first signal lines and the plurality of second signal lines to selectively turn on/off the plurality of chip LEDs.

Here, the chip LED includes a single-color 2-pin chip LED.

Also, the first electrode regions and the second electrode regions forming edge portions of the first and second signal lines are coated with signal pads to which the control signals are inputted.

Here, the first transparent board is shaped as a rectangle; and boundaries electrically isolating the first and the second electrode regions are formed in a diagonal direction or width/length directions of the first transparent board.

Also, the controller sequentially turns on one group of the first signal lines and the second signal lines and selectively turns on the other group while the one group is sequentially turned on, thereby turning on/off the chip LEDs.

Also, the transparent electric sign further comprises a filler filled between the first transparent board and the second transparent board.

In accordance with yet another aspect of the present invention, there is provided a chip LED comprising: a LED chip emitting a single color; a pair of first electrodes which are electrically connected to one of anode and cathode of the LED chip and exposed to the outside; and a pair of second electrodes which are electrically connected to the other of the anode and the cathode of the LED chip and exposed to the outside to diagonally cross the pair of first electrodes.

Here, the chip LED further comprises a LED board on which the first electrodes and the second electrodes are mounted, wherein the LED chip is connected to the first electrodes and the second electrodes mounted on the LED board, and the first electrodes and the second electrodes are bent from one face of the LED board, on which the LED chip is mounted, toward the other face of the LED board, such that the first and second electrodes are exposed to the outside.

Also, the pair of first electrodes are electrically isolated from each other and mounted on the face of the LED board, on which the LED chip is connected. The chip LED further comprises a jumper line electrically connecting the pair of first electrodes, such that the pair of first electrodes are electrically connected to each other.

In accordance with yet another aspect of the present invention, there is provided a line forming chip comprising: a pair of first electrodes which are connected to a pair of electrode regions, respectively, which are located in the diagonal direction of four electrode regions, and electrically connect the pair of electrode regions to each other; and a pair of second electrodes which are connected to a pair of remaining electrode regions of the four electrode regions, respectively, and electrically connect the pair of remaining electrode regions to each other.

Here, the pair of first electrodes are electrically isolated from each other and mounted on the face to which the LED chip is connected. The line forming chip further comprises a jumper line electrically connecting the pair of first electrodes, such that the pair of first electrodes are electrically connected to each other.

### ADVANTAGEOUS EFFECTS

As described above, the present invention provides a transparent, thin electric sign which is made of transparent material, for displaying moving images using LEDs that is operable under low power consumption and has a long life span, and a chip LED applied thereto.

### BRIEF DESCRIPTION OF THE DRAWINGS

The above and other objects, features, and other advantages of the present invention will be more clearly understood from the following detailed description taken in conjunction with the accompanying drawings, in which:

FIG. 1 is a perspective view illustrating a transparent electric sign according to the present invention;

FIG. 2 is a cross-sectional view illustrating the transparent electric sign of FIG. 1;

FIG. 3 to FIG. 5 show views illustrating the configuration of a chip LED according to the present invention;

FIG. 6 is an example of a circuit pattern formed by electrode regions and chip LEDs of the transparent electric sign of FIG. 1;

FIG. 7 is a view illustrating an equivalent circuit of the circuit pattern of FIG. 6;

FIG. 8 is another example of a circuit pattern formed by electrode regions and chip LEDs of the transparent electric sign of FIG. 1; and

FIG. 9 and FIG. 10 are views describing a circuit pattern for another embodiment of a transparent electric sign according to the present invention.

### BEST MODE FOR CARRYING OUT THE INVENTION

Now, preferred embodiments of the present invention will be described in detail with reference to the annexed drawings. The concept of the word, ‘transparent,’ in the present application is not limited to materials through which light passes 100%, but instead is extended to materials which are transparent to the naked eye. Specifically, the word ‘transparent’ in this application refers to a concept which includes a certain degree of transparency.

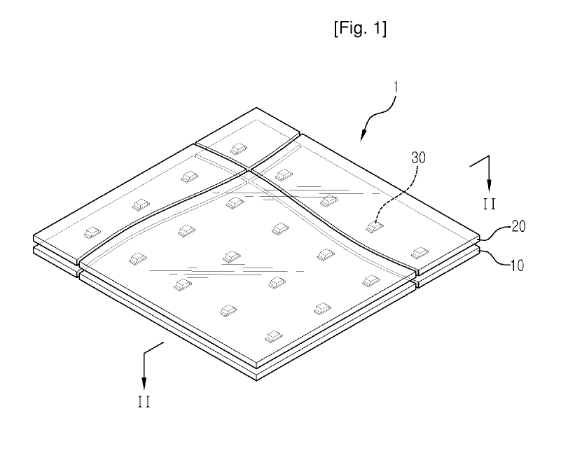

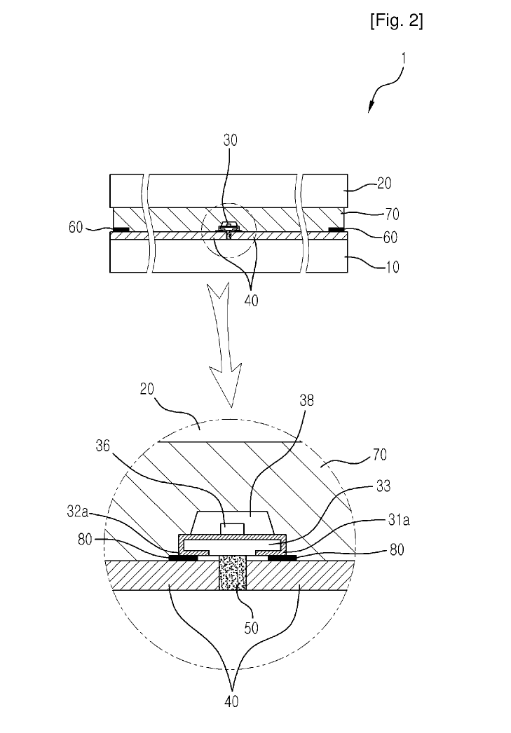

As shown in FIG. 1 and FIG. 2, the transparent electric sign comprises at lease one chip LED 30, a first transparent board 10, a second transparent board 10, a transparent electrode 40, and a controller 100.

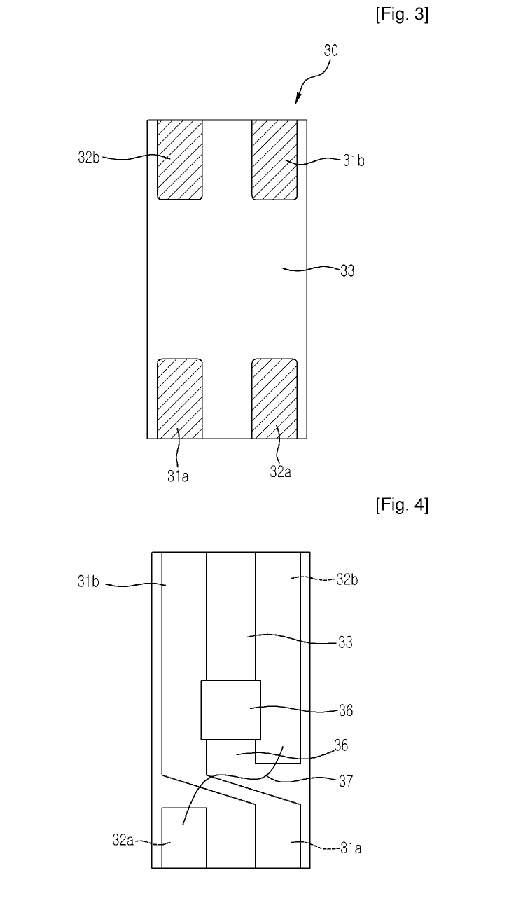

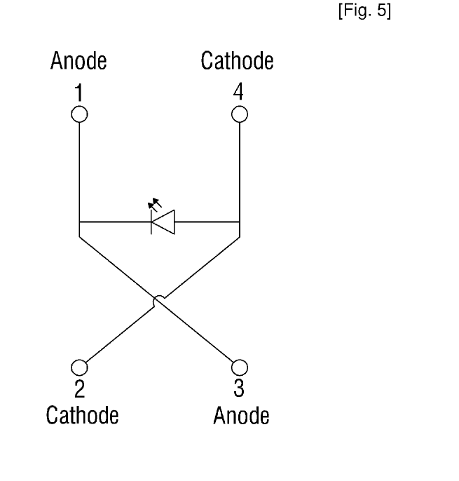

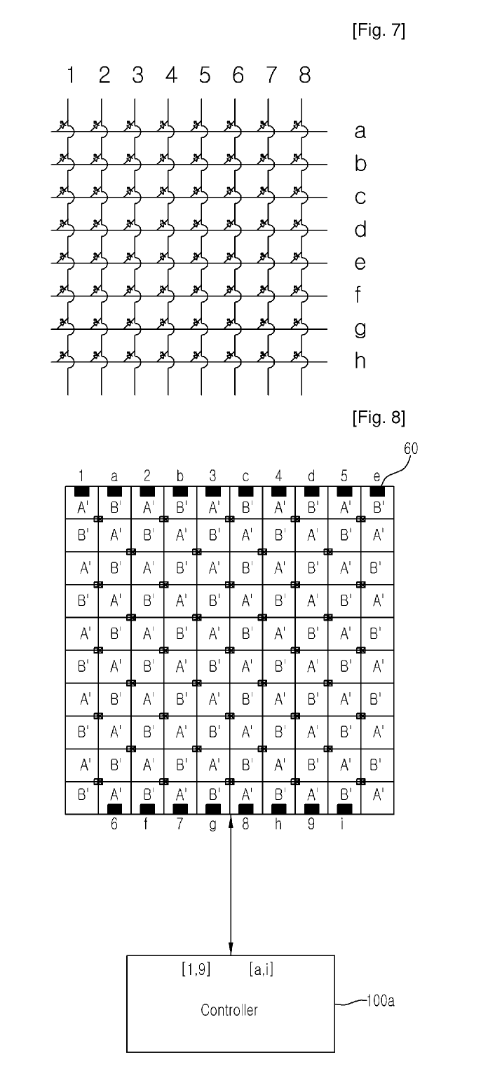

Referring to FIG. 3 to FIG. 5, the chip LED 30 comprises a LED chip 36, a pair of first electrodes 31a and 31b, and a pair of second electrodes 32a and 32b. As shown in FIG. 6 and FIG. 8, the chip LED 30 is formed as a single chip and adhered to the transparent electrode 40. The present invention will be described based on a LED chip 36 of surface mount device (SMD) type, which enables the transparent electric sign to enhance its transparency.

The LED chip 36 is used as a light source emitting a single colored light. The transparent electric sign displays images the LED chip 36 is turned on and off.

The first electrodes 31a and 31b are electrically connected to one of the anode and the cathode of the LED chip 36, and the second electrode 32a and 32b are electrically connected to the other of the anode and the cathode of the LED chip 36. The present invention will be hereinafter described based on an embodiment where the first electrodes 31a and 31b are connected to the anode of the LED chip 36 and the second electrodes 32a and 32b are connected to the cathode of the LED chip 36. Here, the first electrodes 31a and 31b are hereinafter referred to as anode electrodes 31a and 31b, and the second electrode 32a and 32b are hereinafter referred to as cathode electrodes 32a and 32b.

The pair of anode electrodes 31a and 31b and the pair of cathode electrodes 32a and 32b are formed to be exposed outside the chip LED 30. Thus, the exposed anode electrodes 31a and 31b and the exposed cathode electrodes 32a and 32b are adhered to a first electrode region A and to a second electrode region B of the transparent electrode 40. As a result, the chip LED can be turned on and off as power is supplied through the first electrode regions A and the second electrode regions B.

Here, the pair of anode electrodes 31a and 31b and the pair of cathode electrodes 32a and 32b are mounted on a LED board 33. FIG. 3 shows a face of the chip LED 30, to which the first electrode regions A and the second electrode regions B are adhered. FIG. 4 shows a face of the chip LED 30, to which the LED chip 36 is adhered.

Here, the pair of anode electrodes 31a and 31b and the pair of cathode electrodes 32a and 32b are bent form one face of the LED board 33, on which the LED chip 36 is mounted, toward the other face of the LED board 33, such that they can be exposed to the outside.

As shown in FIG. 3 and FIG. 4, both parts of the pair of anode electrodes 31a and 31b are integrally formed on the face of the LED board 33, to which the LED chip 36 is adhered. On the other hand, the cathode electrodes 32a and 32b electrically isolated from each other, which are mounted on the face of the LED board 33, to which the LED chip 36 is adhered. The cathode electrodes 32a and 32b are electrically connected to each other through jumper line 37.

The chip LED 30 configured as described above has a circuit configuration as shown in FIG. 5. In such a circuit configuration, preferably, the pair of anode electrodes 31a and 31b are arranged diagonally to each other. Also, the pair of cathode electrodes 32a and 32b are arranged diagonally to each other. Namely, the pair of cathode electrodes 32a and 32b are exposed to the outside from the lower side of the chip LED 30 such that they are diagonally crossed by the pair of anode electrodes 31a and 31b.

Meanwhile, the first transparent board 10 is formed as a plate made of transparent materials, such as transparent glass, poly carbonate (PC), or acrylic. The present invention will be described based on an embodiment in which the first transparent board 10 is shaped as an approximately rectangular plate and made of glass materials.

Similar to the first transparent board 10, the second transparent board 10 is shaped to correspond to the first transparent board 10, and also made of the same materials as the first transparent board 10. Although the present invention is described based on the embodiment in which the first transparent board 10 and the second transparent board 10 are alike to each other, the skilled person in the art will easily appreciate that they don't have to be the same shape.

Here, in the case that the first transparent board 10 and/or the second transparent board 10 are made of transparent glass materials, the first transparent board 10 and/or the second transparent board 10 may be made of half tempered glass materials. Thus, it may be prevented that transparencies of the first transparent board 10 and/or the second transparent board 10 are decreased because of scratches, and that the first transparent board 10 and/or the second transparent board 10 are broken because of external impacts. Also, a curving phenomenon which occurs when the first transparent board 10 and/or the second transparent board 10 are made of fully tempered glass materials is prevented. Also, the first transparent board 10 and/or the second transparent board 10 made of half tempered glass can minimize increase of resistance of transparent electrode 40 more than those made of fully tempered glass.

Meanwhile, the transparent electrode 40 is formed as one of materials, such as indium tin oxide (ITO), indium zinc oxide (IZO), liquid polymer, is coated to the first transparent board 10.

Referring to FIG. 6, the transparent electrode 40 forms a plurality of first electrode regions A and a plurality of second electrode regions B which are each arrayed in a matrix form. The first electrode regions A and the second electrode regions B are alternatively arrayed on the first transparent board 10. Namely, one first electrode region A is formed to adjoin four second electrode regions B. Similarly, one second electrode region B is formed to adjoin four first electrode regions A.

Here, the first electrode regions A, the second electrode regions B, the first electrode region A, and the second electrode region B are coated to the first transparent board 10 in a state where they are all electrically isolated to each other. FIG. 6 shows an embodiment where boundaries between the first electrode regions A and the second electrode regions B are diagonally formed on the first rectangular transparent board 10 shaped as the rectangular plate.

As shown in FIG. 6, the first electrode regions A and the second electrode region B are each shaped like a rectangle. For example, one first electrode region A adjoins another first electrode region A such that their neighboring vertexes can be adjacent to each other. In addition, the first electrode regions A and the second electrode regions B are arrayed such that their neighboring sides can be adjacent to each other.

Meanwhile, the pair of anode electrodes 31a and 31b of the chip LED 30 are each connected to the pair of first electrode regions A which are mutually adjacent to each other. Also, the pair of cathode electrodes 32a and 32b are each connected to the pair of second electrode regions B adjacent to the first electrode region A to which the anode electrodes 31a and 31b are connected. For example, as shown in FIG. 6, when the first electrode regions A and the second electrode regions B are formed like a rectangle, the chip LED 30 is adhered to a area at which two edges of the pair of neighboring first electrode regions A and two edges of the pair of neighboring second electrode regions B meet.

Similarly, other chip LEDs 30 are also adhered to the areas as described above, arraying in the row direction (hereinafter referred to as ‘first direction’ and column direction (hereinafter referred to as ‘second direction’). Here, the chip LEDs 30 are adhered to the transparent board such that the first electrode regions A form first signal lines 1˜8 in the first direction and the second electrode regions B form second signal lines a˜h in the second direction. As shown in FIG. 6, the chip LED 30 are adhered to the edge areas, respectively, placing over the first and the second electrode region A and B. More specifically, a plurality of first signal lines 1˜8 (FIG. 6 shows 8 first signal lines) are formed along the first electrode regions A in the first direction, and a plurality of second signal lines a˜h (FIG. 6 shows 8 second signals lines) are formed along the second electrode regions B in the second direction.

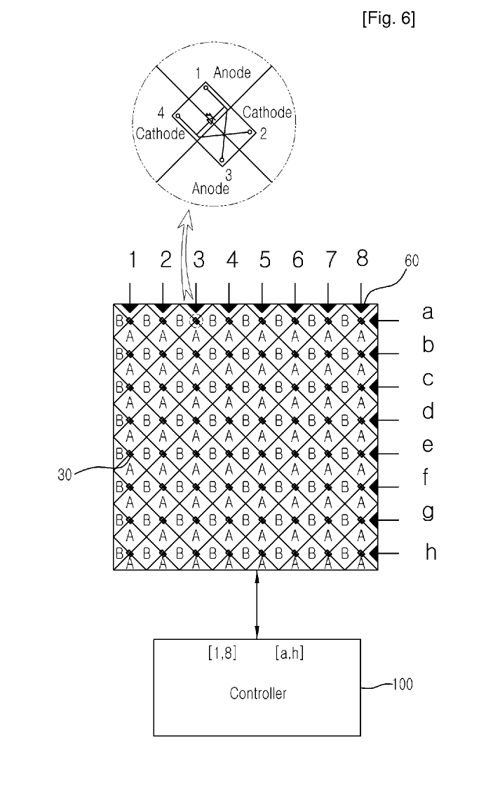

Based on the above-described array manner, the first electrode regions A and the second electrode regions B and the plurality of chip LEDs 30 may be arrayed to form a circuit pattern whose equivalent circuit is illustrated in FIG. 7. The respective chip LEDs 30 are turned on and off as control signals are supplied to the first signal lines 1˜8 and the second signal lines a˜h. Namely, the respective chip LEDs 30 are turned on/off as turn on/off control signals are supplied through the first signals line 1˜8 and the second signal lines a˜h. As the turn on/off of the plurality of chip LEDs 30 is controlled, the transparent electric sign can display moving images.

To form the circuit pattern of FIG. 7, the conventional electrically-illuminated sign must be made up of a two-layered printed circuit board (PCB) or two or more PCBs. But, the transparent electric sign 1, according to the present invention, is implemented using only single-layered transparent electrode 40 as the first electrode regions A and the second electrode regions B are formed on the first transparent board 10 and then the chip LED 30 is adhered to form the circuit pattern of FIG. 7. Therefore, the transparent electric sign 1 of the present invention can be much thinner than the conventional sign. The transparent electric sign 1 can also enhance its transparency.

A controller 100 according to the present invention selectively supplies control signals for turning on/off the first signal lines 1˜8 and the second signal lines a˜h to the chip LEDs 30 to display moving images. Referring to FIGS. 6 and 7, such an operation by the controller 100 is described as follows: the controller 100 sequentially turns on one group of the first signal lines 1˜8 and the second signal lines a˜h, for example, the first signal lines 1˜8, and, at the same time, turns on corresponding one(s) of the second signal lines a˜h, to turn on corresponding chip LEDs 30. Here, the transparent electric sign 1 may form one frame for moving images as the sequentially turned-on time of the first signal lines 1˜8 is shortened and corresponding second signal lines a˜h are turned on within a single sequentially turned-on time of the first signal lines 1˜8.

Here, the controller 100 takes the first signal lines 1˜8 and the second signal lines a˜h as the addresses to the chip LEDs 30. Therefore, to display an image or moving images, the controller 30 can selectively apply control signals for turning on/off corresponding chip LEDs to corresponding addresses.

Meanwhile, signal pads 60 to which control signals from the controller 100 are inputted, are coated to the first electrode regions A and the second electrode regions B forming the edges of the first signal lines 1˜8 and the second signal lines a˜h. Although the present invention is described based on an embodiment in which the signal pads 60 are coated to the upper edge of the first electrode regions A and the right edge of the second electrode regions B, as shown in FIG. 6, the skilled person can easily appreciate that the positions of the signal pads 60 would not limited by those of the embodiment.

Here, the signal pads 60 are formed on the edges as a single-side or both-sided electro-conductive adhesive tape made of copper, aluminum, or silver paste is adhered to the edges. Also, the signal pads 60 may be also formed on the edges as silver paste is printed by a screen print method.

Meanwhile, FIG. 8 shows another embodiment of a circuit pattern formed by first electrode regions A′, second electrode regions B′ and chip LEDs 30. In this embodiment, the boundaries electrically isolating the first electrode regions A′ and the second electrode regions B′ are formed in the width and length directions of a rectangular first transparent board 10. When the chip LEDs 30 are adhered to the areas each of which the boundaries are crossed, first signal lines 1˜9 and the second signal lines a˜i are formed to diagonally cross each other.

In terms of the positions of the signal pads 60, the circuit pattern of FIG. 8 is different from that of FIG. 6. On the other hand, when the embodiment of FIG. 8 displays moving images formed by the embodiment of FIG. 6, the controller 100 of FIG. 8 may apply control signals different from those of FIG. 6 to the signal pads 60.

As such, as the circuit patterns illustrated in FIG. 6 and FIG. 8 are formed using the chip LEDs 30, each of which has the pair of anode electrodes 31a and 31b and the pair of cathode electrodes 32a and 32b. The chip LEDs 30 can be closely arrayed at intervals, for example, of less than 1 cm, thereby implementing the transparent electric sign 1 with a high resolution.

Also, as the circuit pattern is formed using a single layered transparent electrode 40, the thickness of the transparent electric sign 1 can be reduced at a higher rate than the conventional sign. In addition, as the transparent board and the transparent electrode 40 are made of transparent materials, the transparent electric sign 1 can enhance its aesthetic appearance based on transparency.

Referring to FIG. 2, the transparent electric sign 1 according to the present invention may further include filler 70 filled between the first transparent board 10 and the second transparent board 10. Here, the filler 70 protects the chip LEDs 30 against damage. Also, the filler 70 allows the first transparent board 10 and the second transparent board 10 to adhere to each other at a predetermined distance, which enable a use of glass material for transparent board. The filler 70 according to the present invention is implemented by one of PVB film, EVA film, and liquid filler of a series of resins.

Also, in the present invention, the chip LEDs 30 may be adhered to the transparent electrode 40 using the electro-conductive adhesive 80. The present invention is described based on the electro-conductive adhesive 80 implemented by silver conductor or silver paste which is suitable for a screen print method. Preferably, the silver conductor or silver paste has a viscosity of 100˜150 kcps and a surface resistance of 50 m/sq whose conditions make it adhere to glass well. The present invention is described based on the embodiment where silver paste has a viscosity of 100˜150 kcps and a group of conductive epoxy bonds is used. Therefore, when being filled between the first electrode regions A and the second transparent boards B through a laminating process, the filler 70 can maintain its adhesive force.

Additionally, the transparent electric sign 1 according to the present invention may further include a non-electro-conductive adhesive 50 to adhere the chip LEDs 30. The non-electro-conductive adhesive 50 adhere the bodies of the chip LEDs 30 to the portions forming the boundaries between the first electrode regions A and/or the second electrode regions B of the transparent board 10. Specifically, such an adhering process of the non-electro-conductive adhesive can prevent the chip LEDs 30 from deviating from their positions due to a vibration or shake generated while the chip LEDs 30 are adhered to the transparent electrode 40 of the first transparent board 10, or, while the filler 70 is injected to the gap between the first transparent board 10 and the second transparent board 10.

In addition, the non-electro-conductive adhesive 50 serves to prevent the first electrode regions A and the second electrode regions B from electrical connection, which is called an electrical short. Such connection is made as the electro-conductive adhesive 80 flows from a electrode region to another electrode region while the electro-conductive adhesive 80 adheres the anode electrodes 31a and 31b and the cathode electrodes 32a and 32b to the first electrode regions A and the second electrode regions B, respectively. To prevent such connection, the non-electro-conductive adhesive 50 is formed to be protruded from the surface of the first transparent board 10 more than those of the first electrode regions A and the second electrode regions B, facing the chip LED 30.

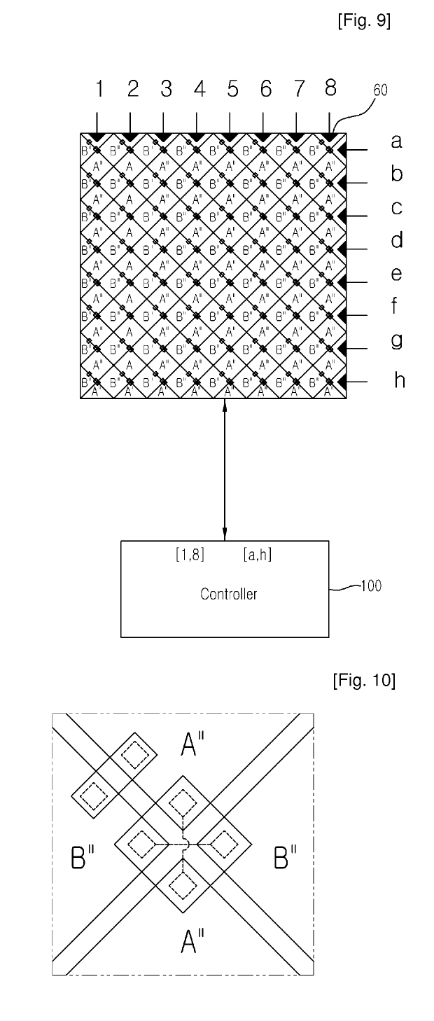

Referring to FIG. 9 and FIG. 10, a circuit pattern of another embodiment of the transparent electric sign according to the present invention is described as follows. Regarding the same elements between the transparent electric sign of FIG. 9 and FIG. 10 and the transparent electric sign of FIG. 6 and FIG. 8, they cite the same reference numbers, and, their detailed description is omitted now. Also, the configuration of the transparent electric sign which is not shown in FIG. 9 and FIG. 10 can be deemed to correspond to that of FIG. 6 and FIG. 8.

As shown in FIG. 9, the transparent electric sign according to another embodiment of the present invention employs a single colored chip LED 30′ with two leads having one anode electrode 31a′ and one cathode electrode 32a′.

To form an equivalent circuit pattern like that of FIG. 7, line forming chip 30″ or cross jumper chip is adhered to a pair of first electrode regions A″ and a pair of second electrode regions B″ which are adjacent to each other. Here, the line forming chip 30″ include a pair of first electrodes 31a″ and 31b″ and a pair of second electrodes 32a″ and 32b″. The pair of first electrodes 31a″ and 31b″ and the pair of second electrodes 32a″ and 32b″ are diagonally crossed and exposed to the outside.

Also, the pair of first electrodes 31a″ and 31b″ of the line forming chip 30″ are electrically connected to each other, and to the pair of neighboring first electrode regions A″, respectively, such that the pair of neighboring first electrode regions A″ can be electrically connected to each other. Similarly, the pair of second electrodes 32a″ and 32b″ are electrically connected to each other, and to the pair of neighboring second electrode regions B″, respectively, such that the pair of neighboring second electrode regions B″ can be electrically connected to each other. Therefore, the plurality of first electrode regions A″ form a plurality of first signal lines 1′˜8′ in the first direction through the first electrodes 31a″ and 31b″ of the line forming chip 30″, and the plurality of second electrode regions B″, form a plurality of second signal lines a′˜h′ in the second direction through the second electrodes 32a″ and 32b″ of the line forming chip 30″.

Here, the anode electrode 31a′ is connected to the first electrode region A″ to be connected to the first signal lines 1′˜8′, and the cathode electrode 32a′ is connected to the second electrode region B″ to be the second signal lines a′˜h′. Therefore, such connections make the embodiment possible to form the equivalent circuit pattern as shown in FIG. 6.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

### INDUSTRIAL APPLICABILITY

The present invention can be widely applied to a transparent electric sign and chip LEDs applied thereto as the transparent electric sign can display moving images.

1. A transparent electric sign comprising:
a first transparent board;
a second transparent board being spaced apart from the first transparent board at a predetermined distance and facing the first transparent board;
a transparent electrode for forming a plurality of first electrode regions and a plurality of second electrode regions which are arrayed in a matrix form, respectively, wherein at least one of the plurality of first electrode regions is adjacent to four second electrode regions;
a plurality of chip LEDs adhered to the transparent electrode, wherein the chip LED has a pair of anode electrodes connected to the pair of first electrode regions being adjacent to each other and a pair of cathode electrodes connected to the pair of second electrode regions being adjacent to the pair of first electrode regions to which the anode electrode regions are connected, respectively such that the plurality of first electrode regions form a plurality of first signal lines formed in a first direction and the plurality of second electrode regions form a plurality of second signal lines formed in a second direction crossing the first direction; and
a controller selectively supplying control signals to the plurality of first signal lines and the plurality of second signal lines to selectively turn on/off the plurality of chip LEDs.

2. A transparent electric sign comprising:
a first transparent board;
a second transparent board being spaced apart from the first transparent board at a predetermined distance and facing the first transparent board;
a transparent electrode forming a plurality of first electrode regions and a plurality of second electrode regions which are arrayed in a matrix form, respectively, wherein at least one of the plurality of first electrode regions is adjacent to four second electrode regions;
a plurality of line forming chips adhered to the transparent electrode, wherein the line forming chip has a pair of first electrodes connected to a pair of first electrode regions being adjacent to each other, respectively, and electrically connected to each other, and a pair of second electrodes connected to the pair of second electrode regions, respectively, which are adjacent to the pair of the first electrode regions to which the first electrode is connected, and which are connected to each other, such that the plurality of first electrode regions form a plurality of first signal lines formed in a first direction, and the plurality of second electrode regions form a plurality of second signal lines formed in a second direction crossing the first direction;
a plurality of chip LEDs having an anode electrode connected to one of the first electrode regions to be connected to the first signal line, and a cathode electrode connected to one of the second electrode regions to be connected to the second signal line; and
a controller selectively supplying control signals to the plurality of first signal lines and the plurality of second signal lines to selectively turn on/off the plurality of chip LEDs.

3. The transparent electric sign according to claim 2, wherein the chip LED includes a single-color 2-pin chip LED.

4. The transparent electric sign according to claim 1, wherein the first electrode regions and the second electrode regions forming edge portions of the first and second signal lines are coated with signal pads to which the control signals are inputted.

5. The transparent electric sign according to claim 4, wherein:
the first transparent board is shaped as a rectangle; and
boundaries electrically isolating the first and the second electrode regions are formed in a diagonal direction or width/length directions of the first transparent board.

6. The transparent electric sign according to claim 5, wherein the controller sequentially turns on one group of the first signal lines and the second signal lines and selectively turns on the other group while the one group is sequentially turned on, thereby turning on/off the chip LEDs.

7. The transparent electric sign according to claim 6, further comprising a filler filled between the first transparent board and the second transparent board.

8. A chip LED comprising:
a LED chip emitting a single color;
a pair of first electrodes which are electrically connected to one of anode and cathode of the LED chip and exposed to the outside; and
a pair of second electrodes which are electrically connected to the other of the anode and the cathode of the LED chip and exposed to the outside to diagonally cross the pair of first electrodes.

9. The chip LED according to claim 8, further comprising a LED board on which the first electrodes and the second electrodes are mounted,
wherein the LED chip is connected to the first electrodes and the second electrodes mounted on the LED board, and the first electrodes and the second electrodes are bent from one face of the LED board, on which the LED chip is mounted, toward the other face of the LED board, such that the first and second electrodes are exposed to the outside.

10. The chip LED according to claim 9, wherein the pair of first electrodes are electrically isolated from each other and mounted on the face of the LED board, on which the LED chip is connected;
further comprising a jumper line electrically connecting the pair of first electrodes, such that the pair of first electrodes are electrically connected to each other.

11. A line forming chip comprising:
a pair of first electrodes which are connected to a pair of electrode regions, respectively, which are located in the diagonal direction of four electrode regions, and electrically connect the pair of electrode regions to each other; and
a pair of second electrodes which are connected to a pair of remaining electrode regions of the four electrode regions, respectively, and electrically connect the pair of remaining electrode regions to each other.

12. The line forming chip according to claim 11, wherein the pair of first electrodes are electrically isolated from each other and mounted on the face to which the LED chip is connected;
further comprising a jumper line electrically connecting the pair of first electrodes, such that the pair of first electrodes are electrically connected to each other.

13. The transparent electric sign according to claim 2, wherein the first electrode regions and the second electrode regions forming edge portions of the first and second signal lines are coated with signal pads to which the control signals are inputted.

14. The transparent electric sign according to claim 13, wherein:
the first transparent board is shaped as a rectangle; and
boundaries electrically isolating the first and the second electrode regions are formed in a diagonal direction or width/length directions of the first transparent board.

15. The transparent electric sign according to claim 14, wherein the controller sequentially turns on one group of the first signal lines and the second signal lines and selectively turns on the other group while the one group is sequentially turned on, thereby turning on/off the chip LEDs.

16. The transparent electric sign according to claim 15, further comprising a filler filled between the first transparent board and the second transparent board.

17. The transparent electric sign according to claim 3, wherein the first electrode regions and the second electrode regions forming edge portions of the first and second signal lines are coated with signal pads to which the control signals are inputted.

18. The transparent electric sign according to claim 17, wherein:
the first transparent board is shaped as a rectangle; and
boundaries electrically isolating the first and the second electrode regions are formed in a diagonal direction or width/length directions of the first transparent board.

19. The transparent electric sign according to claim 18, wherein the controller sequentially turns on one group of the first signal lines and the second signal lines and selectively turns on the other group while the one group is sequentially turned on, thereby turning on/off the chip LEDs.

20. The transparent electric sign according to claim 19, further comprising a filler filled between the first transparent board and the second transparent board.
